(19) United States
(12) Patent Application Publication
(10) Pub. No.: US 2026/0251708 A1
(43) Pub. Date: Aug. 27, 2026

(54) Scan Operation Methods and Devices

(71) Applicant: Arm Limited, Cambridge (GB)

(72) Inventors: Shruti Aggarwal, Austn, TX (US); Andy Wangkun Chen, Austin, TX (US); Yew Keong Chong, Austin, TX (US)

(21) Appl. No.: 19/060,440

(22) Filed: Feb. 21, 2025

(51) Int. Cl. G01R 31/317; G01R 31/3185

(52) U.S. Cl. CPC G01R 31/31727; G01R 31/318536; G01R 31/318541

(57) ABSTRACT

A method for scan operations includes performing, by a circuit, a first scan operation in a scan-shift operation mode using a first port clock signal; and performing, by the circuit, a second scan operation in a scan-capture operation mode using a second port clock signal independent from the first port clock signal. Another method for scan operations includes providing, by a scan chain architecture circuitry, a clock signal to an input latch and one or more output latches of a scan operation circuitry; and performing a scan operation using the clock signal. A circuit for scan operations includes scan operation circuitry comprising at least: an input latch and one or more output latches; and control circuitry, where the control circuitry is configured to transmit a respective first or second clock signal to control the scan operation circuitry in a first or second scan operation mode.

### I. FIELD

The present disclosure is generally related to systems, methods, and devices for scan operations.

### II. DESCRIPTION OF RELATED ART

In modern digital circuit designs, ensuring reliable operation across multiple clock domains is a critical challenge, particularly in systems involving scan shift and scan capture operations. Synchronization issues arise when clock signals from different domains, such as CLKA and CLKB, interact. These challenges are exacerbated by clock skew, which leads to overlap failures and inconsistencies in internal clock signals.

Clock skew can cause internal glitches, such as double pulses, which disrupt the intended functionality of scan paths. This issue becomes more pronounced in designs where control clocks for multiple ports (e.g., QA and QB) depend on signals derived from both CLKA and CLKB. Testing has shown that while minor skew can be tolerated, higher skew levels result in operational failures, including glitches in critical internal signals. Further complicating the issue is the use of an OR-based clocking mechanism, which, while simplifying clock activation, introduces logical inconsistencies under high-skew conditions. Instead of generating a single clean clock pulse, the OR function can produce multiple overlapping pulses, compromising the reliability of scan operations. Hence, there is a pressing need in the art for a robust solution to address these challenges, mitigate clock skew effects, eliminate internal glitches, and ensure reliable functionality across multiple clock domains.

### III. BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1 is a diagram of an example circuit in accordance with various implementations described herein.

FIG. 2 is a table in accordance with various implementations described herein.

FIG. 3 is a diagram of an example circuit in accordance with various implementations described herein.

FIG. 4 is a table in accordance with various implementations described herein.

FIG. 5 is an operational method in accordance with various implementations described herein.

FIG. 6 is an operational method in accordance with various implementations described herein.

FIG. 7 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### IV. DETAILED DESCRIPTION

Implementations of the present disclosure are described below with reference to the drawings. In the description, common features are designated by common reference numbers throughout the drawings.

In one implementation, the present disclosure describes a method for scan operations including performing, by a circuit, a first scan operation in a scan-shift operation mode using a first port clock signal; and performing, by the circuit, a second scan operation in a scan-capture operation mode using a second port clock signal independent from the first port clock signal.

In another implementation, the present disclosure describes for scan operations including providing, by a scan chain architecture circuitry, a clock signal to an input latch and one or more output latches of a scan operation circuitry; and performing a scan operation using the clock signal.

In another implementation, the present disclosure describes a circuit for scan operations. The circuit includes scan operation circuitry having at least: an input latch and one or more output latches; and control circuitry, where the control circuitry is configured to transmit a respective first or second clock signal to control the scan operation circuitry in a first or second scan operation mode.

Modern scan design for testing digital circuits often requires seamless synchronization between multiple clock domains, particularly in scenarios involving scan shift and scan capture operations. In configurations with multiple latches, such as those involving Port QA and Port QB (P1-P2 latch architecture), clock skew and overlap between two clock domains, CLKA and CLKB, introduce significant challenges.

In scan shift mode (DFT=1, SEA=1) and scan capture mode (DFT=1, SEA=0), the P1-P2 latch control clock is derived from both CLKA and CLKB through an OR function. This design ensures that whichever clock—CLKA or CLKB—is active first, the system can proceed with operations. However, this reliance on both clock signals introduces a critical dependency that makes the system susceptible to clock skew issues. For example, the overlap of CLKA and CLKB, particularly in high-skew conditions, creates glitches in the internal clock signals. These glitches manifest as double pulses on critical internal latch signals. Specifically, the OR function used to resolve clock inputs in the P1-P2 latch introduces a “double glitch” due to skew-induced overlap between the wclk signal (derived from CLKB) and the nlat_en signal (derived from CLKA). Ideally, the internal clock signal should generate a single consistent pulse. However, due to the higher skew between CLKA and CLKB, two overlapping pulses are produced; thereby, causing functional failures. For instance, in a 1R1RW design, the combination of scan shift and scan capture operations adds additional complexity to clock signal synchronization. In certain cases, waveform analysis reveals that the OR function, while addressing basic clock activation, fails to eliminate glitches in scenarios with high skew. This leads to overlap failures, particularly in the DB to QA latch path, where both CLKA and CLKB signals converge.

Inventive aspects relate to scan-based testing techniques for digital circuits, particularly multi-port memory architectures such as two-port memory (e.g., 1R1W, 1R1RW) and other configurations. Scan shift and scan capture operations are essential for verifying circuit functionality and identifying faults and may be performed in any order for flexible testing. Advantageously, the inventive aspects isolate clocking for scan operations by assigning a distinct clock signal to each function, eliminating dependency on both clocks. Scan shift mode operates exclusively on CLKA (first port clock signal), while scan capture mode uses only CLKB (second port clock signal). This separation prevents clock skew issues, ensuring stable scan performance and eliminating scan flip-flop glitches that previously arose from overlapping or misaligned CLKA and CLKB signals.

The claimed invention is particularly beneficial for multi-port memory architectures, including 1R1W and 1R1RW, where precise scan timing is required between different ports. In two-port memory, for example, the first port may be a read port, while the second may be a read-write port (1R1RW) or a write port (1R1W). This design ensures independent scan operation for each port, making scan operations fully skew-free while enabling precise timing validation between Port A and Port B. By ensuring independent execution of scan shift and scan capture with dedicated clock sources, various aspects of the claimed invention eliminate clock overlap issues while maintaining flexibility in scan execution order. The control circuitry ensures CLKA and CLKB remain mutually exclusive, preventing signal interference and enabling predictable test execution. While an alternative implementation may allow a single clock signal (CLKA or CLKB) to drive both scan shift and scan capture, the primary implementation separates clocks, ensuring a fully skew-free scan operation.

Advantageously, the schemes and techniques presented herein provide a scalable and efficient solution for scan-based testing in multi-port memory architectures, eliminating scan flip-flop glitches, mitigating CLKA-CLKB skew issues, and enabling precise scan operation execution with independent clock domains. By removing timing dependencies between scan shift and scan capture, the claimed invention significantly improves the accuracy and reliability of scan testing in modern memory designs.

Certain definitions have been provided herein for reference. A two-port memory (i.e., 2-port memory) is a subset of multi-port memory architectures that includes exactly two independent access ports that enable simultaneous or independent operations. In one example, these include a read port for retrieving data and a read-write port for either reading or writing data. This configuration supports concurrent read and write operations, improving performance and operational efficiency. A multi-port memory is a memory architecture with two or more independent access ports, allowing multiple read and/or write operations to occur simultaneously or independently. Each port operates with its own address and control signals, enabling concurrent access by multiple users or processes. This configuration is commonly used in high-performance systems to improve parallelism and throughput.

In various implementations, mission mode refers to the normal operational state of a multi-port memory, where the memory performs its intended read and write functions as part of the system's standard execution, without engaging in test or scan operations. In addition, scan shift mode is a test operation of a scan architecture in a multi-port memory where data is sequentially shifted through scan chains for debugging or verification purposes, allowing controlled input to and observation of internal states. Moreover, scan capture mode is a test operation of a scan architecture in a multi-port memory where captured data from internal states is stored in scan cells and then observed, enabling verification of circuit functionality and timing.

Design for Testability (DFT) refers to design techniques and methodologies integrated into a circuit or system to facilitate efficient testing and debugging. These techniques enable the identification and isolation of manufacturing defects or design flaws by incorporating specialized test structures, such as scan chains, built-in self-test (BIST), and boundary scan. In addition, Design for Test RAM Bypass (DFTRAMBYP) refers to a specialized test mode in memory designs that bypasses normal memory operations to facilitate direct testing or debugging of specific components, such as latches, logic, or interconnects, without interacting with the main RAM array. This mode is typically used in Design for Testability (DFT) implementations to isolate and evaluate critical memory elements.

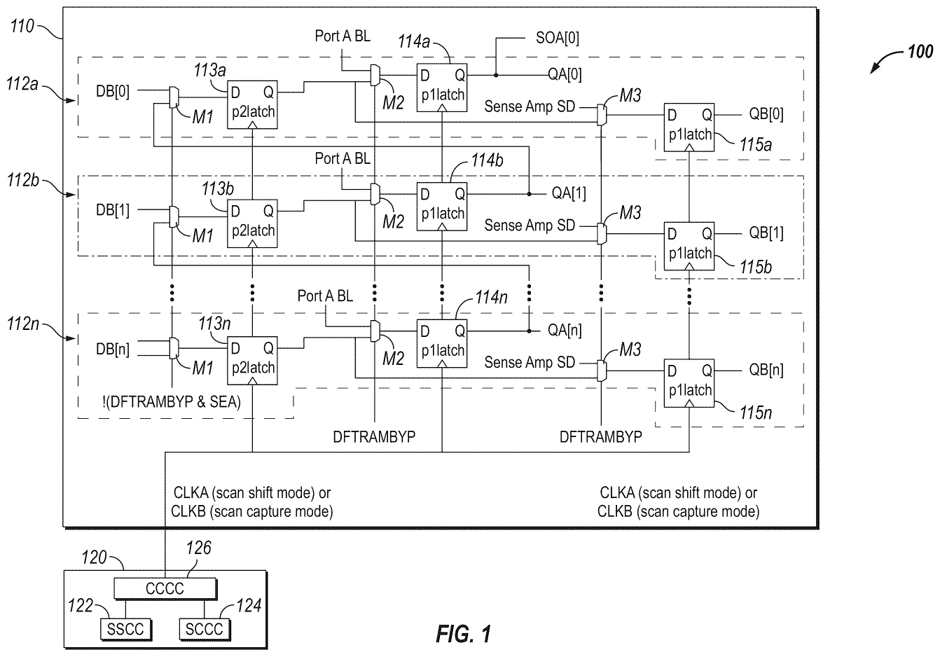

Referring to FIG. 1, a diagram 100 of an example scan chain architecture (i.e., circuit 100) for scan operations in a one-read, one-read-write (1R1RW) memory according to example implementations is shown. In various implementations, the scan chain architecture 100 in FIG. 1 may be implemented as a system or a device having integrated circuitry (IC) and components that are arranged and coupled together as an assemblage or some combination of parts that may provide for physical circuit layout design and related structures. In various instances, a method of designing, fabricating, building and/or providing the scan chain architecture 100 as an integrated system or device may involve use of IC circuit components described herein so as to thereby implement various configurable scan chain architecture schemes and techniques associated therewith. Moreover, the scan chain architecture 100 may be integrated with various computing circuitry and related components on a single chip, and also, the scan chain architecture 100 may be implemented within embedded systems for automotive, electronic, mobile, server and Internet-of-things (IoT) applications.

As illustrated, the example scan chain architecture (i.e., circuit 100) can include scan operation circuitry 110 and clock control circuitry 120 (i.e., control circuitry). In various implementations, the scan operation circuitry 110 includes one or more rows (e.g., a plurality of rows) of scan chains 112 (e.g., 112a, 112b, . . . , 112n, etc.). For instance, each row (e.g., each of the one or more rows of scan chains 112) can include an input latch 113 (e.g., 113a, 113b, . . . , 113n) (i.e., p2latch) and one or more output latches 114 (e.g., 114a, 114b, . . . , 114n); 115 (e.g., 115a, 115b, . . . 115n) (i.e., p1latch). Also, the control circuitry is configured to transmit a respective first port clock signal or second port clock signal (e.g., CLKA or CLKB) or derivations thereof to control (e.g., transmit to; initiate) the scan operation circuitry 100 in a first or second scan operation mode.

In some implementations, as shown, each row of the scan chain architecture (i.e., circuit 100) includes a first multiplexer (M1) that receives a first data input signal (e.g., DB0, . . . DB[n-1], DB[n]) and a second data input signal (e.g., an output signal from an output latch 114 of a subsequent row). In addition, in certain cases, each first multiplexer (M1) is configured to provide respective data input signals to the input latch 113 (e.g., p2latch) based on the !(DFTRAMBYP and scan enable port A (SEA)) signals. In turn, for each row, a second multiplexer (M2) can receive the output from the input latch 113 as well as a Port A bitline (BL) signal, and select and transmit either signal as an output transmitted to a first output latch 114 based on the DFTRAMBYP signal. Further, in one example, the output of the first output latch 114 may be a respective QA output or Scan Out A output (e.g., a latched output signal, QA[0], SOA[0]).

Moreover, in turn, for each row, a third multiplexer (M3) can receive the output from the input latch 113 as well as a sense amplifier SD signal (e.g., sense amp SD), and select and transmit either signal as an output transmitted to a second output latch 115 based on the DFTRAMBYP signal. For example, in this context, a sense amplifier SD signal (e.g., Sense Amp SD) can be an output of sense amplifier during memory read operation. In certain cases, a sense amplifier (not shown) can detect and amplify small voltage differences from memory bitlines (not shown) to reliably determine stored data. In such cases, a sense amplifier enable signal would govern when the sense amplifier is active, ensuring proper timing and preventing conflicts during read or test operations. Further, as one example, the output of the second output latch 115 may be a respective QB output (e.g., a latched output signal, QB[0]).

In certain implementations, the first scan operation mode corresponds to a scan-shift mode and the second scan operation mode corresponds to a scan-capture mode. In various aspects, for each row, each of the input latch 113 and the one or more output latches 114, 115 are configured to receive either the first port clock signal (e.g., CLKA) or the second port clock signal (e.g., CLKB) based on a scan operation mode. In certain aspects, for each row, the input latch 113 corresponds to a write port and the one or more output latches 114, 115 correspond to respective one or more read ports.

In various implementations, the control circuitry 120 includes scan shift clock control circuitry (SSCC) 122, scan capture clock control circuitry (SCCC) 124, and central clock control circuitry (CCCC) 126. The SSCC 122 is responsible for providing a scan shift clock signal (e.g., CLKA, the first port clock signal) to the scan operation circuitry 110 via the CCCC 126, ensuring that scan shift operations are controlled exclusively by CLKA. Similarly, the SCCC 124 generates a scan capture clock signal (e.g., CLKB, the second port clock signal) and routes it to the scan operation circuitry 110 through the CCCC 126, ensuring that scan capture operations are exclusively driven by CLKB. The CCCC 126 functions as a central selector, determining whether the system operates in scan-shift mode or scan-capture mode, ensuring precise timing and clock control to mitigate clock skew effects.

To effectively manage scan operation modes, the CCCC 126 selectively enables scan shift or scan capture operation modes based on predefined logic conditions. Instead of NOR2 mixing, an alternative logic implementation such as OAI mixing may be used to improve control signal timing and reduce unintended clock interference. For example, the NDFT signal, GWEN signal, and DFTSEA signal may be utilized for clock selection logic. The NDFT (Non-DFT Mode Signal) is typically used to indicate when normal functional mode is active, allowing seamless switching between mission and scan operations. The GWEN (Global Write Enable Signal) plays a role in determining active write phases, particularly in scan-based memory designs. The DFTSEA (Design-for-Test Scan Enable A Signal) provides scan enable functionality specific to Port A's scan path.

In some implementations, for the P1-QB latch, the SAE (Sense Amplifier Enable) latch is controlled by the lat_en signal (Latch Enable Signal) during scan shift mode and by the sae signal (Sense Amplifier Enable Signal) during scan capture mode. This allows the P1-QB latch to selectively switch between scan shift and scan capture states, avoiding contention between clock domains. Additionally, during scan shift mode, the SEA signal (Scan Enable A Signal) is isolated from CLKB by integrating it with the DFTSEA signal, preventing interference between scan shift and scan capture operations.

The SSCC 122 ensures that a dedicated clock control signal (CLKA) is used exclusively for scan shift operations. In one implementation, NAND3 mixing of the NGTP signal (e.g., a complement of the Global Timing Pulse), DFTSEA signal, and a combination of LREN signal (Latch Read Enable), GWEN signal, and NDFT signal is used to regulate clock selection. This configuration effectively blocks the wclk signal (CLKB) during scan shift mode, ensuring that only lat_en (CLKA) is enabled for the P2 latch in scan shift mode. Since the P2 latches are used for both QA and QB, and the P1 latch for QA is driven by an OR function of wclk (CLKB) and nlat signal (CLKA-derived signal), this approach guarantees that nlat_en (CLKA) is enabled in scan shift mode, while wclk (CLKB) is activated in scan capture mode. Advantageously, this separation ensures that scan shifting and scan capturing occur without clock contention or unintended state transitions.

The SCCC 124 is designed to ensure that CLKB is used exclusively for scan capture operations, preventing unwanted interactions between CLKA and CLKB during testing. To achieve this, DFTSEA and DFTNSE signals (Design-for-Test Scan Enable A and B, respectively) are generated by combining DFT and SEA signals using optimized logic implementations. In certain implementations, rather than using NOR2 mixing, a NOR3 mixing of NGTP, DFTNSE, and LRENA (Latch Read Enable A Signal) is performed. This configuration ensures that the nlat_en signal (CLKA) for P1-QA is blocked in scan capture mode, allowing only wclk_local (CLKB) to be enabled for P1-QA. Advantageously, this prevents timing conflicts and signal overlap, ensuring that each scan operation mode operates with its dedicated clock source.

Advantageously, such inventive clock control schemes and techniques, as described herein, effectively mitigate clock skew issues by strictly isolating scan shift operations to CLKA and scan capture operations to CLKB, eliminating scan flip-flop glitches and ensuring reliable multi-port memory scan functionality. By leveraging intelligent clock signal gating and selective enablement of scan logic, this system enables precise scan-based fault detection and verification while maintaining robust and interference-free memory testing.

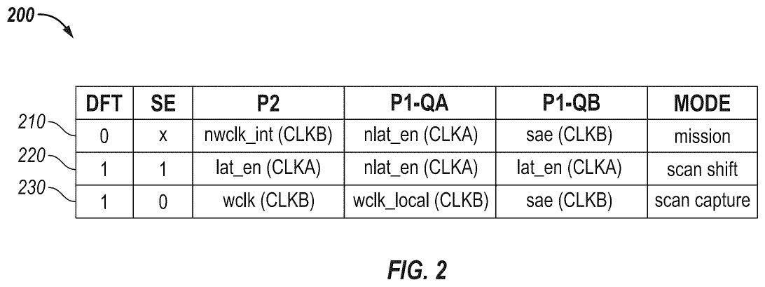

Referring to FIG. 2, an example table 200 corresponding to the circuit 100 in FIG. 1 according to example implementations is shown. In one example, the circuit 100 may operate in mission mode 210. In mission mode 210, referring to a normal operational state of the memory architecture, the memory (e.g., 1R1RW) (not shown) can perform its intended read and write functions as part of the system's standard execution without engaging in test or scan operations. As illustrated, in one example, the mission mode 210 can be enacted when the DFT signal is set to a digital “0”. For such an implementation, the input latch P2 (e.g., input latch 113) is configured to receive CLKB (e.g., nwclk_int signal) while the first and second output latches P1-QA (e.g., output latch 114) and P1-QB (e.g., output latch 115) are configured to receive CLKA (e.g., nlat_en signal) and CLKB (e.g., sae signal) respectively.

In a second example, the circuit 100 may operate in scan shift mode 220. For example, scan shift mode 220 is a test operation in the memory architecture where data is sequentially shifted through scan chains for debugging or verification purposes, allowing controlled input to and observation of internal states. As illustrated, in one example, the scan shift mode 220 can be enacted when the DFT signal is set to a digital “1” and the scan enable signal (SE) is also set to a digital “1”. For such an implementation, the input latch P2 (e.g., input latch 113) is configured to receive CLKA (e.g., lat_en signal), while the first and second output latches P1-QA (e.g., output latch 114) and P1-QB (e.g., output latch 115) are also configured to receive CLKA (e.g., nlat_en signal) and CLKA (e.g., lat_en signal). As may be appreciated, in the implementation, clock control for each input and output latches 113, 114, 115 is dependent only on CLKA signal and its derived clock variation(s).

In a third example, the circuit 100 may operate in scan capture mode 230. As may be appreciated, scan capture mode 230 is a test operation in the memory architecture where captured data from internal states is stored in scan cells and then observed, enabling verification of circuit functionality and timing. As illustrated, in one example, the scan capture mode 230 can be enacted when the DFT signal is set to a digital “1” and the scan enable signal (SE) is set to a digital “0”. For such an implementation, the input latch P2 (e.g., input latch 113) is configured to receive CLKB (e.g., wclk signal), while the first and second output latches P1-QA (e.g., output latch 114) and P1-QB (e.g., output latch 115) are also configured to receive CLKB (e.g., wclk_local signal) and CLKB (e.g., sae signal). As may be appreciated, in the implementation, clock control for each input and output latches 113, 114, 115 is dependent only on CLKB signal and its derived clock variation(s).

Advantageously, for each separate mode, each of the latches: input latch (P2) and one or more output latches (e.g., P1-QA, P1-QB) can be effectuated using a same clock signal (including its derivations) that would be distinct from another operational mode.

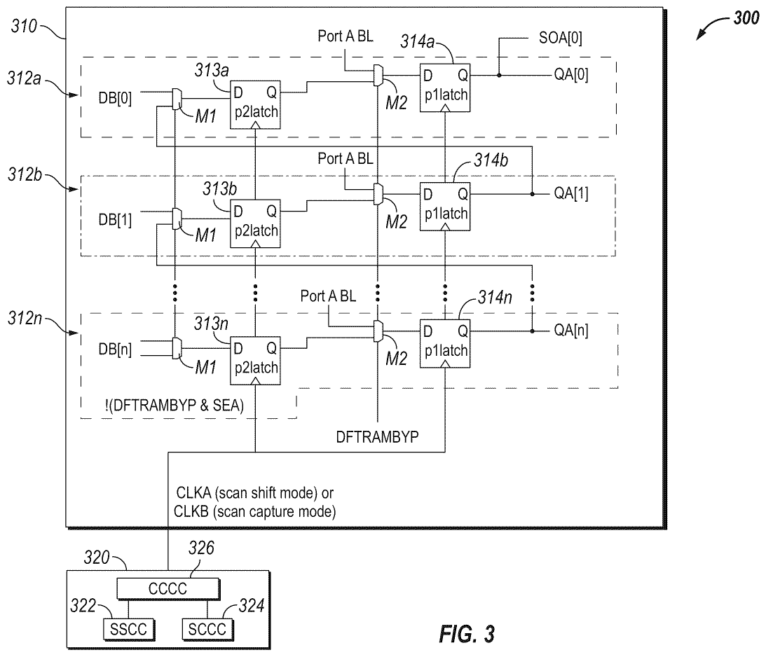

Referring to FIG. 3, a diagram 300 of an example scan chain architecture (i.e., circuit 300) for scan operations in a one-read, one-write (1R1W) memory according to example implementations is shown. In various implementations, the scan chain architecture 300 in FIG. 3 may be implemented as a system or a device having integrated circuitry (IC) and components that are arranged and coupled together as an assemblage or some combination of parts that may provide for physical circuit layout design and related structures. In various instances, a method of designing, fabricating, building and/or providing the scan chain architecture 100 as an integrated system or device may involve use of IC circuit components described herein so as to thereby implement various configurable scan chain architecture schemes and techniques associated therewith. Moreover, the scan chain architecture 300 may be integrated with various computing circuitry and related components on a single chip, and also, the scan chain architecture 100 may be implemented within embedded systems for automotive, electronic, mobile, server and Internet-of-things (IoT) applications.

As illustrated, the example scan chain architecture (i.e., circuit 300) can include scan operation circuitry 310 and clock control circuitry 120 (i.e., control circuitry). In various implementations, the scan operation circuitry 310 includes one or more rows (e.g., a plurality of rows) of scan chains 312 (e.g., 312a, 312b, . . . , 312n, etc.). For instance, each row (e.g., each of the one or more rows of scan chains 112) can include an input latch 313 (e.g., 313a, 313b, . . . 313n) (i.e., p2latch) and an output latch 314 (e.g., 314a, . . . 314[n-1], 314[n]) (i.e., p1latch). Also, the control circuitry is configured to transmit a respective first port clock signal or second port clock signal (e.g., CLKA or CLKB) or derivations thereof to control (e.g., transmit to; initiate) the scan operation circuitry 300 in a first or second scan operation mode.

In some implementations, as shown, each row of the scan chain architecture (i.e., circuit 300) includes a first multiplexer (M1) that receives a first data input signal (e.g., DB0, . . . DB[n-1], DB[n]) and a second data input signal (e.g., an output signal from an output latch 314 of a subsequent row). In addition, in certain cases, each first multiplexer (M1) is configured to provide respective data input signals to the input latch 313 (e.g., p2latch) based on the !(DFTRAMBYP and scan enable port A (SEA)) signals. In turn, for each row, a second multiplexer (M2) can receive the output from the input latch 313 as well as a Port A bitline (BL) signal, and select and transmit either signal as an output transmitted to a first output latch 314 based on the DFTRAMBYP signal. Further, in one example, the output of the first output latch 314 may be a respective QA output or Scan Out A output (e.g., a latched output signal, QA[0], SOA[0]).

In various implementations, the scan chain architecture 300 in FIG. 3 is similar to that of the scan chain architecture in FIG. 1 with the exception that the scan chain architecture 300 does not include respective second output latches (e.g., P1-QB) and associated circuitry. By doing so, the scan chain architecture 300 may be optimized for 1R1W memory. In various aspects, the control circuitry 120 in FIG. 3 is substantially similar to that of the control circuitry 120 as described with reference to FIG. 1. Hence, for brevity, the section has not been repeated.

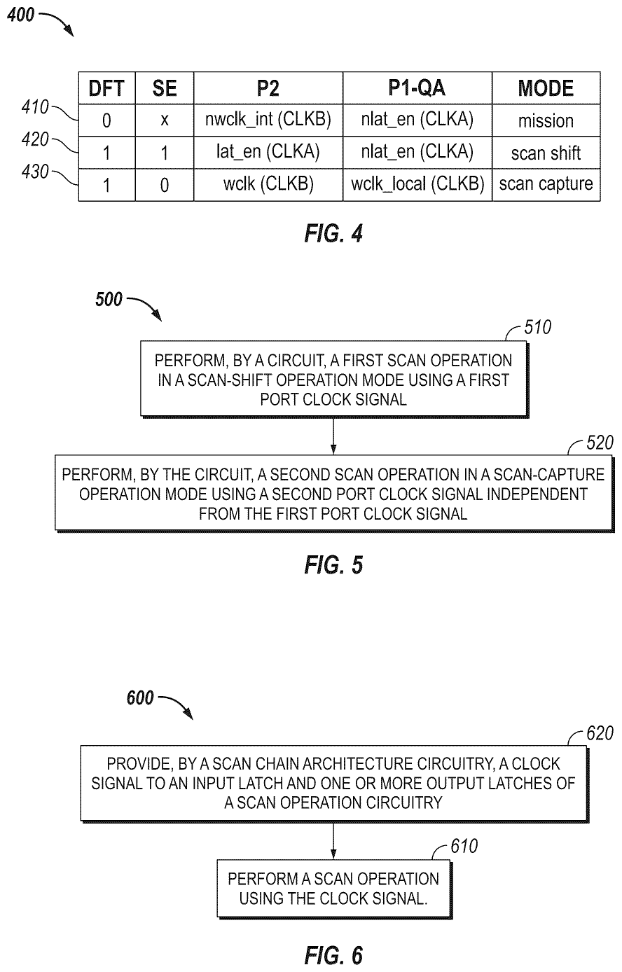

Referring to FIG. 4, an example table 400 corresponding to the circuit 300 in FIG. 3 according to example implementations is shown. In one example, the circuit 300 may operate in mission mode 410. In mission mode 410, referring to a normal operational state of the memory architecture, the memory (e.g., 1R1W) (not shown) can perform its intended read and write functions as part of the system's standard execution without engaging in test or scan operations. As illustrated, in one example, the mission mode 410 can be enacted when the DFT signal is set to a digital “0”. For such an implementation, the input latch P2 (e.g., input latch 313) is configured to receive CLKB (e.g., nwclk_int signal), while the first output latch P1-QA (e.g., output latch 114) is configured to receive CLKA (e.g., nlat_en signal).

In a second example, the circuit 300 may operate in scan shift mode 420. For example, scan shift mode 420 is a test operation in the memory architecture where data is sequentially shifted through scan chains for debugging or verification purposes, allowing controlled input to and observation of internal states. As illustrated, in one example, the scan shift mode 420 can be enacted when the DFT signal is set to a digital “1” and the scan enable signal (SE) is also set to a digital “1”. For such an implementation, the input latch P2 (e.g., input latch 113) is configured to receive CLKA (e.g., lat_en signal), while the first output latch P1-QA (e.g., output latch 114) is also configured to receive CLKA (e.g., nlat_en signal). As may be appreciated, in the implementation, clock control for both of the input latch 113 and output latch 114 are dependent only on CLKA signal and its derived clock variation(s).

In a third example, the circuit 300 may operate in scan capture mode 430. As may be appreciated, scan capture mode 430 is a test operation in the memory architecture where captured data from internal states is stored in scan cells and then observed, enabling verification of circuit functionality and timing. As illustrated, in one example, the scan capture mode 430 can be enacted when the DFT signal is set to a digital “1” and the scan enable signal (SE) is set to a digital “0”. For such an implementation, the input latch P2 (e.g., input latch 313) is configured to receive CLKB (e.g., wclk signal), while the first output latch P1-QA (e.g., output latch 114) is also configured to receive CLKB (e.g., wclk_local signal). As may be appreciated, in the implementation, clock control for both of the input latch 113 and the output latch 114 are dependent only on CLKB signal and its derived clock variation(s).

Advantageously, for each separate mode, both of the latches: input latch (P2) and output latch (e.g., P1-QA) can be effectuated using a same clock signal (including its derivations) that would be distinct from another operational mode.

Referring to FIG. 5, a flowchart of an example operational method 500 (i.e., procedure) is shown. Advantageously, in various implementations, the method 500 describes the capability for scan operations (e.g., scan-shift and scan-capture operations) and, for example, (i.e., scan-based testing: to verify functionality and identify faults in digital circuits (e.g., 2-port memory and other multi-port memory). The method 500 may be implemented with reference to implementation as shown with reference to FIGS. 1-4.

At block 510, the example method 500 includes: performing, by a circuit, a first scan operation in a scan-shift operation mode using a first port clock signal. For instance, as described with reference to FIGS. 1-4, a scan operation circuit 100 (e.g., in conjunction with the computer 800) is configured to perform by a first scan operation in a scan-shift operation mode a first port clock signal (e.g., CLKA).

At block 520, the example method 500 includes: performing, by the circuit, a second scan operation in a scan-capture operation mode using a second port clock signal independent from the first clock signal. For instance, as described with reference to FIGS. 1-4, the same scan operation circuit 100 (e.g., in conjunction with the computer 800) is configured to perform by a second scan operation in a scan-capture operation mode using a second port clock signal (e.g., CLKB) independent from the first port clock signal.

In certain implementations, the first scan operation is performed using solely the first clock signal (and derivatives thereof), and the second scan operation is performed using solely the second clock signal (and derivatives thereof). In various cases, the circuit includes multi-port memory (e.g., two-port memory or more). In one example, the circuit includes first and second ports, where the first port includes a read port and the second port comprises a read-write port (e.g., 1R1RW memory). In another example, the circuit includes first and second ports, where the first port includes a read port and the second port comprises a write port (e.g., 1R1W memory, where there is no QB port).

According to some aspects, the performance of the first scan operation includes: providing, by scan shift clock control circuitry of the circuit, the first clock signal (CLKA) to an input latch and first and second output latches. In certain aspects, the performance of the second scan operation includes: providing, by scan capture clock control circuitry of the circuit, the second clock signal (CLKB) to an input latch and first and second output latches.

In certain cases, the first scan operation is performed in the scan shift mode by scan shift clock control circuitry of the circuit, and the second scan operation is performed in the scan capture mode by scan capture control circuitry of the circuit. In certain aspects, the control circuit provides the first and second clock signals. In various scenarios, the circuit comprises: an input latch (P2) and one or more output latches (P1-QA, P1-QB) (e.g., 1R1W, 1R1RW).

Referring to FIG. 6, a flowchart of an example operational method 600 (i.e., procedure) is shown. Advantageously, in various implementations, the method 600 describes the capability for scan operations (e.g., scan-shift and scan-capture operations); for example, scan-based testing: to verify functionality and identify faults in digital circuits (e.g., 2-port memory and other multi-port memory). The method 600 may be implemented with reference to implementation as shown with reference to FIGS. 1-4.

At block 610, the example method 600 includes: providing, by a circuitry, a clock signal to an input latch and one or more output latches of scan operation circuitry of the circuitry. For instance, as described with reference to FIGS. 1-4, providing, by control circuitry 120 of scan architecture circuitry 100, a clock signal (e.g., either CLKA or CLKB) to an input latch (P2) and one or more output latches (P1-QA, P1-QB) (e.g., 1R1W, 1R1RW) of scan operation circuitry.

At block 620, the example method 600 includes: performing a scan operation using the clock signal. For instance, as described with reference to FIGS. 1-4, performing a scan operation (e.g., scan-shift or scan-capture operation) using the (same) clock signal (e.g., either CLKA or CLKB).

In certain implementations, for the method 600, the scan operation includes a scan-shift operation or a scan-capture operation. Also, in certain examples, the method 600 includes: 1) providing, by the scan chain architecture circuitry 100, a second clock signal (e.g., the other of CLKA or CLKB) to the input latch (P2) and the one or more output latches (P1-QA, P1-QB) (e.g., 1R1W, 1R1RW) of the circuitry; and 2) performing a second scan operation (e.g., the other of scan-shift or scan-capture) using the second clock signal. In some cases, the input latch corresponds to a write port; and the one or more output latches correspond to respective one or more read ports.

Inventive aspects of the present invention address the challenges posed by clock skew in 2-port memory architectures, such as 1R1W, 1R1RW, and other multi-port memory designs. To mitigate issues arising from the misalignment of CLKA (A port) and CLKB (B port) in real-world implementations, the claimed invention introduces a novel clocking approach that eliminates the need for an “OR” function and ensures reliable scan operations.

In this solution, scan shift and scan capture operations are assigned distinct clock dependencies. For example, in certain implementations, Scan Shift Mode can rely exclusively on CLKA to drive the input latch and output latches for both Port A and Port B, while Scan Capture Mode can utilize CLKB for the same latches. By separating these functions, advantageously, such approaches avoid scan flip-flop clock glitches and ensure seamless operation regardless of clock skew. Accordingly, such schemes and techniques ensure precise testing and timing alignment based on a specific clock used, improving overall reliability and efficiency. This inventive methodology not only resolves clock skew challenges but also enhances the adaptability of memory architectures by optimizing the use of CLKA and CLKB for scan operations. Hence, aspects of the present invention provide a robust and scalable solution for ensuring consistent functionality across various 2-port memory configurations.

FIG. 6 illustrates example hardware components in the computer system 600 that may be used to facilitate and generate the inventive circuit design/memory architecture output. In certain implementations, the example computer system 600 (e.g., networked computer system and/or server) may include EDA tool 624 to execute software based on the procedure as described with reference to the methods as described herein. For example, FIG. 6 illustrates example hardware components in the computer system 600 that may be used for dynamic pulse width adjustment, e.g., selective write pulse extension during a write operation in EVA=0 mode. In certain implementations, the EDA tool 624 may be included as a feature of an existing compiler software program. In certain implementations, an EDA (Electronic Design Automation) tool 624 would automate signal detection and control logic configuration for the schemes and techniques as described herein (e.g., with reference to the circuit 100 illustrated in FIG. 1 and the flow diagram 300 illustrated in FIG. 3).

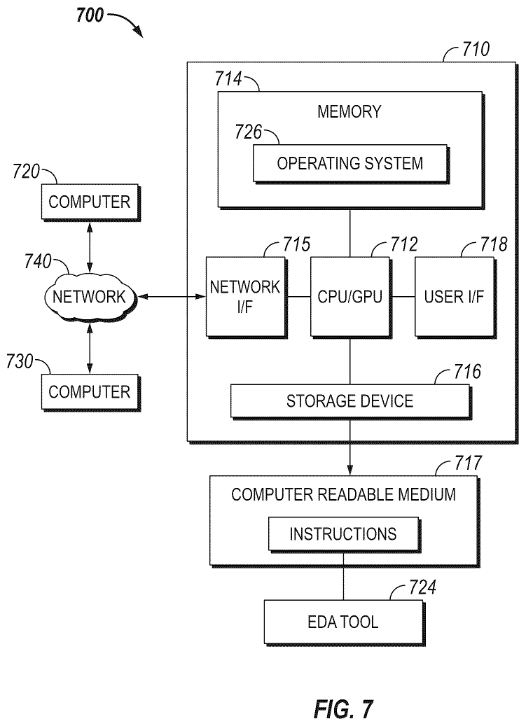

FIG. 7 illustrates example hardware components in the computer system 700 that may be used to facilitate and generate the inventive circuit design and memory architecture output. In certain implementations, the computer system 700 (e.g., a networked computer system and/or server) includes Electronic Design Automation (EDA) tool 724, which executes software procedures based on the methodologies described herein. For example, FIG. 7 illustrates example hardware components that may be used for scan-based testing in multi-port memory architectures, particularly implementing clock isolation techniques for scan-shift and scan-capture operations. In some implementations, the EDA tool 724 may be integrated as a feature within an existing compiler software program. In certain cases, the EDA tool 724 automates signal detection, clock domain separation, and scan control logic configuration for the schemes and techniques described herein (e.g., in reference to circuits 100, 300 and the flow diagrams 600, 700).

In various implementations, the EDA tool 724 is configured to synthesize the inventive circuit design by automating the generation, verification, and optimization of scan shift and scan capture clock control logic to implement skew-free scan operations. The tool ensures that scan shift mode is performed solely using CLKA and scan capture mode is performed solely using CLKB, eliminating clock skew-related scan flip-flop glitches. The tool first detects the presence of multi-port memory configurations (e.g., 1R1W, 1R1RW) and analyzes their scan architecture to determine clock dependencies. It then generates control logic to ensure that scan shift operations propagate exclusively through CLKA-driven paths, while scan capture operations are confined to CLKB-driven paths, thereby isolating the two clock domains.

In such implementations, the EDA tool 724 automates the synthesis of custom circuit modules, including scan shift clock control circuitry, scan capture clock control circuitry, and clock-gating logic to ensure synchronized scan operation execution. Functional simulations validate the design under various scenarios, such as scan shift-only, scan capture-only, and sequential scan operations with different CLKA-CLKB skew conditions. The tool also configures timing constraints to ensure that scan shift and scan capture operations remain independent and unaffected by clock skew.

Additionally, the EDA tool 724 performs critical path analysis and timing optimization to prevent unwanted glitches in scan flip-flops due to clock domain interactions. By isolating scan shift and scan capture clocking, the tool ensures minimal clock-to-output timing variations, reducing potential setup and hold timing violations. Furthermore, layout optimizations minimize routing congestion, ensuring that control logic integration does not introduce additional signal interference or propagation delays. Power analysis quantifies dynamic power savings by reducing unnecessary clock toggling in scan flip-flops, ensuring compliance with power, performance, and area (PPA) goals.

To validate implementation robustness, the EDA tool 724 executes formal verification procedures to confirm equivalence between the synthesized circuit and the intended skew-free scan architecture. The tool generates test vectors for post-silicon validation, allowing verification of the scan operation methodology under real-world manufacturing conditions. The finalized design seamlessly integrates into larger processing units (e.g., CPUs, GPUs, or system-on-chip (SoC) architectures), providing a scalable and efficient solution for scan-based testing in multi-port memory architectures. By ensuring a robust, timing-independent scan operation workflow, the EDA tool 724 enables high-performance and reliable memory circuit validation across diverse multi-port memory configurations.

The procedures (e.g., 500, 600), for example, may be stored as program instructions as instructions 717 in the computer-readable medium of the storage device 716 (or alternatively, in memory 714) that may be executed by the computer 710, or networked computers 720, 730, other networked electronic devices (not shown), or a combination thereof. In certain implementations, each of the computers 710, 720, 730 may be any type of computer, computer system, or other programmable electronic device. Further, each of the computers 710, 720, 730 may be implemented using one or more networked computers, e.g., in a cluster or other distributed computing system.

In certain implementations, the system 700 may be used with semiconductor integrated circuit (IC) designs that contain all standard cells, all blocks, or a mixture of standard cells and blocks. In a particular example implementation, the system 700 may include in its database structures: a collection of cell libraries, one or more technology files, a plurality of cell library format files, a set of top design format files, one or more Open Artwork System Interchange Standard (OASIS/OASIS. MASK) files, and/or at least one EDIF file. The database of the system 700 may be stored in one or more of memory 714 or storage devices 716 of computer 710 or in networked computers 720, 730.

In one implementation, the computer 700 includes a central processing unit (CPU) 712 (or graphics processing unit (GPU) or neural processing unit (NPU) in certain implementations) having at least one hardware-based processor coupled to a memory 714. The memory 714 may represent random access memory (RAM) devices of main storage of the computer 710, supplemental levels of memory (e.g., cache memories, non-volatile or backup memories (e.g., programmable or flash memories)), read-only memories, or combinations thereof. In addition to the memory 714, the computer system 700 may include other memory located elsewhere in the computer 710, such as cache memory in the CPU 712, as well as any storage capacity used as a virtual memory (e.g., as stored on a storage device 716 or on another computer coupled to the computer 710).

The computer 710 may further be configured to communicate information externally. To interface with a user or operator (e.g., a circuit design engineer), the computer 710 may include a user interface (I/F) 718 incorporating one or more user input devices (e.g., a keyboard, a mouse, a touchpad, and/or a microphone, among others) and a display (e.g., a monitor, a liquid crystal display (LCD) panel, a light-emitting diode (LED) display panel, and/or a speaker, among others). In other examples, user input may be received via another computer or terminal. Furthermore, the computer 710 may include a network interface (I/F) 715, which may be coupled to one or more networks 740 (e.g., a wireless network) to enable communication of information with other computers and electronic devices. The computer 710 may include analog and/or digital interfaces between the CPU 712 and each of the components 714, 715, 716, and 718. Further, other non-limiting hardware environments may be used within the context of example implementations.

The computer 710 may operate under the control of an operating system 726 and may execute or otherwise rely upon various computer software applications, components, programs, objects, modules, data structures, etc. (such as the programs associated with the procedure 700 and related software). The operating system 726 may be stored in the memory 714. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States), i5/OS® (a registered trademark of IBM Corp.), and others as will occur to those of skill in the art. The operating system 726 in the example of FIG. 7 is shown in the memory 714, but components of the aforementioned software may also, or in addition, be stored at non-volatile memory (e.g., on storage device 716) and/or the non-volatile memory (not shown). Moreover, various applications, components, programs, objects, modules, etc. may also execute on one or more processors in another computer coupled to the computer 710 via the network 740 (e.g., in a distributed or client-server computing environment) where the processing to implement the functions of a computer program may be allocated to multiple computers 720, 730 over the network 740.

In example implementations, circuit-related diagrams have been provided in FIGS. 1-7, whose redundant description has not been duplicated in the related description of analogous circuit-related diagrams. It is expressly incorporated that the same diagrams with identical symbols and/or reference numerals are included in each of the embodiments based on its corresponding figure(s).

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the claimed invention. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the claimed invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, where such instructions may execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A method for scan operations:
performing, by a circuit, a first scan operation in a scan-shift operation mode using a first port clock signal; and
performing, by the circuit, a second scan operation in a scan-capture operation mode using a second port clock signal independent from the first port clock signal.

2. The method of claim 1, wherein:
the first scan operation is performed using solely the first clock signal; and
the second scan operation is performed using solely the second clock signal.

3. The method of claim 1, wherein the circuit comprises multi-port memory.

4. The method of claim 1, wherein:
the circuit comprises first and second ports; and
the first port comprises a read port and the second port comprises a read-write port.

5. The method of claim 1, wherein:
the circuit comprises first and second ports; and
the first port comprises a read port and the second port comprises a write port.

6. The method of claim 1, wherein performing the first scan operation comprises:
providing, by scan shift clock control circuitry of the circuit, the first clock signal to an input latch and first and second output latches.

7. The method of claim 1, wherein performing the second scan operation comprises:
providing, by scan capture clock control circuitry of the circuit, the second clock signal to an input latch and first and second output latches.

8. The method of claim 1, wherein:
the first scan operation is performed in the scan shift mode by scan shift clock control circuitry of the circuit.

9. The method of claim 1, wherein:
the second scan operation is performed in the scan capture mode by scan capture control circuitry of the circuit.

10. The method of claim 1, further comprising:
providing, by a circuit, the first and second clock signals.

11. The method of claim 1, wherein:
the circuit comprises: an input latch and one or more output latches.

12. A method for scan operations:
providing, by a scan chain architecture circuitry, a clock signal to an input latch and one or more output latches of a scan operation circuitry; and
performing a scan operation using the clock signal.

13. The method of claim 12, wherein the scan operation comprises a scan-shift operation or a scan-capture operation.

14. The method of claim 12, further comprising:
providing, by the scan chain architecture circuitry, a second clock signal to the input latch and the one or more output latches of the circuitry; and
performing a second scan operation using the second clock signal.

15. The method of claim 12, wherein:
the input latch corresponds to a write port; and
the one or more output latches correspond to respective one or more read ports.

16. A circuit for scan operations comprising:
scan operation circuitry comprising at least: an input latch and one or more output latches; and
control circuitry, wherein the control circuitry is configured to transmit a respective first or second clock signal to control the scan operation circuitry in a first or second scan operation mode.

17. The circuit of claim 16, wherein:
the first scan operation mode corresponds to a scan-shift mode; and
the second scan operation mode corresponds to a scan-capture mode.

18. The circuit of claim 16, wherein each of the input latch and the one or more output latches is configured to receive either the first clock signal or the second clock signal based on a scan operation mode.

19. The circuit of claim 16, wherein the control circuitry comprises:
scan shift clock control circuitry;
scan capture clock control circuitry of the circuit; and
central clock control circuitry.

20. The circuit of claim 16, wherein:
the input latch corresponds to a write port; and
the one or more output latches correspond to respective one or more read ports.
